(19) United States
(12) Patent Application Publication
(10) Pub. No.: US 2026/0063707 A1
(43) Pub. Date: Mar. 5, 2026

(54) INSPECTION METHOD OF A SEMICONDUCTOR DEVICE AND THE INSPECTION PROGRAM OF THE SEMICONDUCTOR DEVICE

(71) Applicant: Renesas Electronics Corporation, Tokyo (JP)

(72) Inventors: Takashige UTATSU, Tokyo (JP); Kazuhiro SAKAGUCHI, Tokyo (JP); Shinji KUSAKABE, Tokyo (JP)

(21) Appl. No.: 19/289,232

(22) Filed: Aug. 4, 2025

(30) Foreign Application Priority Data
Sep. 4, 2024 (JP) 2024-152402

(51) Int. Cl. G01R 31/28

(52) U.S. Cl. CPC G01R 31/2874; G01R 31/2865; G01R 31/2886

(57) ABSTRACT

An inspection method of a semiconductor device includes inspecting the semiconductor device that is included in a sample placed on a stage of an inspection apparatus. The stage includes a temperature adjustment unit. The temperature adjustment unit includes a plurality of temperature adjustment elements. The plurality of temperature adjustment elements are arranged in a plane parallel to a stage surface of the stage where the sample is placed, and a size of each of the plurality of temperature adjustment elements is smaller than or equal to a size of the semiconductor device in a plain view.

### CROSS-REFERENCE TO RELATED APPLICATIONS

The disclosure of Japanese Patent Application No. 2024-152402 filed on Sep. 4, 2024, including the specification, drawings and abstract is incorporated herein by reference in its entirety.

### BACKGROUND

This disclosure relates to a method for inspecting semiconductor devices and an inspection program for semiconductor devices.

There are disclosed techniques listed below.
[Patent Document 1] Japanese Unexamined Patent Application Publication No. 2001-156228
[Patent Document 2] Japanese Unexamined Patent Application Publication No. H4-104072
[Patent Document 3] Japanese Unexamined Patent Application Publication No. 2005-164460
[Patent Document 4] Japanese Unexamined Patent Application Publication No. 2018-100838

Patent Document 1 discloses a semiconductor device with a cooling apparatus. The semiconductor device with a cooling apparatus in Patent Document 1 is formed such that a cooling element is adjacent to the substrate on which the semiconductor device is formed. The cooling element is formed on the backside of the portion where the semiconductor device is formed. The cooling element is controlled based on the temperature of the semiconductor device. The cooling capability of the cooling element is set based on the heat generation amount per unit time of the semiconductor device, which is derived in advance. Additionally, the cooling capability of the cooling element is controlled based on the power consumption of the semiconductor device. Furthermore, the cooling capability of the cooling element is controlled based on the operating state of the semiconductor device. The cooling element is formed using a dummy pattern of the semiconductor device. Patent Documents 2 to 4 disclose inspection apparatuses for semiconductor devices.

### SUMMARY

It is desired to enhance the precision of semiconductor device inspections and to accurately inspect the performance of semiconductor devices.

Other challenges and novel features will become apparent from the description of this specification and the accompanying drawings.

According to one embodiment, an inspection method of a semiconductor devices includes a step of inspecting the semiconductor device in a sample placed on the stage of an inspection apparatus for the semiconductor devices. The stage includes a temperature adjustment unit, the temperature adjustment unit includes a plurality of temperature adjustment elements. The plurality of temperature adjustment elements are arranged in a plane parallel to a stage surface of the stage where the sample is placed, and a size of each of the plurality of temperature adjustment elements is smaller than or equal to a size of the semiconductor device in a plain view.

According to one embodiment, an inspection program of a semiconductor device causes a computer to execute inspection of the semiconductor device that is included in a sample placed on a stage of an inspection apparatus for the semiconductor device. The stage includes a temperature adjustment unit. The temperature adjustment unit includes a plurality of temperature adjustment elements. The plurality of temperature adjustment elements are arranged in a plane parallel to a stage surface of the stage where the sample is placed, and a size of each of the plurality of temperature adjustment elements is smaller than or equal to a size of the semiconductor device in a plain view.

According to the above-mentioned embodiment, it is possible to improve the inspection accuracy of semiconductor devices.

### BRIEF DESCRIPTION OF THE DRAWINGS

FIG. 1 is a configuration diagram illustrating an inspection apparatus for semiconductor devices according to a comparative example.

FIG. 2 is a diagram illustrating the issues found by the inventor in the inspection apparatus for semiconductor devices according to a comparative example.

FIG. 3 is a configuration diagram illustrating an inspection apparatus for semiconductor devices according to the first embodiment.

FIG. 4 is a plan view illustrating the temperature adjustment unit in the inspection apparatus for semiconductor devices according to the first embodiment.

FIG. 5 is a diagram illustrating the temperature adjustment element in the inspection apparatus for semiconductor devices according to the first embodiment.

FIG. 6 is a diagram illustrating the positional relationship between the temperature adjustment element and the semiconductor device in the inspection apparatus for semiconductor devices according to the first embodiment.

FIG. 7 is a diagram illustrating the positional relationship between the temperature adjustment element and the circuit block in the inspection apparatus for semiconductor devices according to the first embodiment.

FIG. 8 is a plan view illustrating the position of the circuit block in the semiconductor device in the inspection apparatus for semiconductor devices according to the first embodiment.

FIG. 9 is a diagram illustrating the corresponding relationship between the inspection items and the circuit blocks in the inspection apparatus for semiconductor devices according to the first embodiment.

FIG. 10 is a diagram illustrating the corresponding relationship between the positions of the circuit blocks in the inspection apparatus for semiconductor devices according to the first embodiment.

FIG. 11 is a plan view illustrating the position of the semiconductor device on the wafer in the inspection apparatus for semiconductor devices according to the first embodiment.

FIG. 12 is a diagram illustrating the position of the semiconductor device on the wafer in the inspection apparatus for semiconductor devices according to the first embodiment.

FIG. 13 is a plan view illustrating the position of the temperature adjustment element in the temperature adjustment unit in the inspection apparatus for semiconductor devices according to the first embodiment.

FIG. 14 is a diagram illustrating the position of the temperature adjustment element in the temperature adjustment unit in the inspection apparatus for semiconductor devices according to the first embodiment.

FIG. 15 is a flowchart diagram illustrating the inspection method as an operation of the inspection apparatus for semiconductor devices according to the first embodiment.

FIG. 16 is a flowchart diagram illustrating the inspection method of the inspection apparatus for semiconductor devices according to the first embodiment.

FIG. 17 is a flowchart diagram illustrating the inspection of the semiconductor device to be inspected in the inspection method for semiconductor devices according to the first embodiment.

FIG. 18 is a diagram illustrating the circuit block of the semiconductor device in the inspection apparatus for semiconductor devices according to a comparative example.

FIG. 19 is a diagram illustrating the circuit block of the semiconductor device in the inspection apparatus for semiconductor devices according to the first embodiment.

FIG. 20 is a configuration diagram illustrating an inspection apparatus for semiconductor devices according to the second embodiment.

FIG. 21 is a configuration diagram illustrating an inspection apparatus for semiconductor devices according to the second embodiment.

FIG. 22 is a configuration diagram illustrating an inspection apparatus for semiconductor devices according to the third embodiment.

FIG. 23 is a block diagram illustrating the control unit and storage unit in the inspection apparatus for semiconductor devices according to the third embodiment.

FIG. 24 is a graph illustrating the power change profile applied to the tester and temperature adjustment element in the inspection apparatus for semiconductor devices according to the third embodiment.

FIG. 25 is a flowchart diagram illustrating the inspection of the semiconductor device to be inspected in the inspection method for semiconductor devices according to the third embodiment.

FIG. 26 is a flowchart diagram illustrating the inspection of the semiconductor device to be inspected in the inspection method for semiconductor devices according to the first modified example of the third embodiment.

FIG. 27 is a flowchart diagram illustrating the inspection of the semiconductor device to be inspected in the inspection method for semiconductor devices according to the second modified example of the third embodiment.

### DETAILED DESCRIPTION

For clarity of explanation, the following description and drawings are appropriately omitted and simplified. In the drawings, the same elements are denoted by the same reference numerals, and a repetitive description thereof is omitted as necessary. Some reference numerals may be omitted to prevent the drawings from becoming complicated.

First, in the <Comparative Example>, the inspection apparatus for semiconductor devices according to the comparative example will be described. Then, in the <Problem Recognized by Inventors>, the issues newly found by the inventors regarding the inspection apparatus of the comparative example will be described. Subsequently, in <First Embodiment> to <Third Embodiment>, the inspection apparatus and inspection method for semiconductor devices according to the first to third embodiments will be described in contrast with the comparative example. This will clarify the inspection apparatus and inspection method for semiconductor devices according to the present embodiment. Note that the comparative example and the issues newly found by the inventor are also within the scope of the technical concept of the embodiments.

### COMPARATIVE EXAMPLE

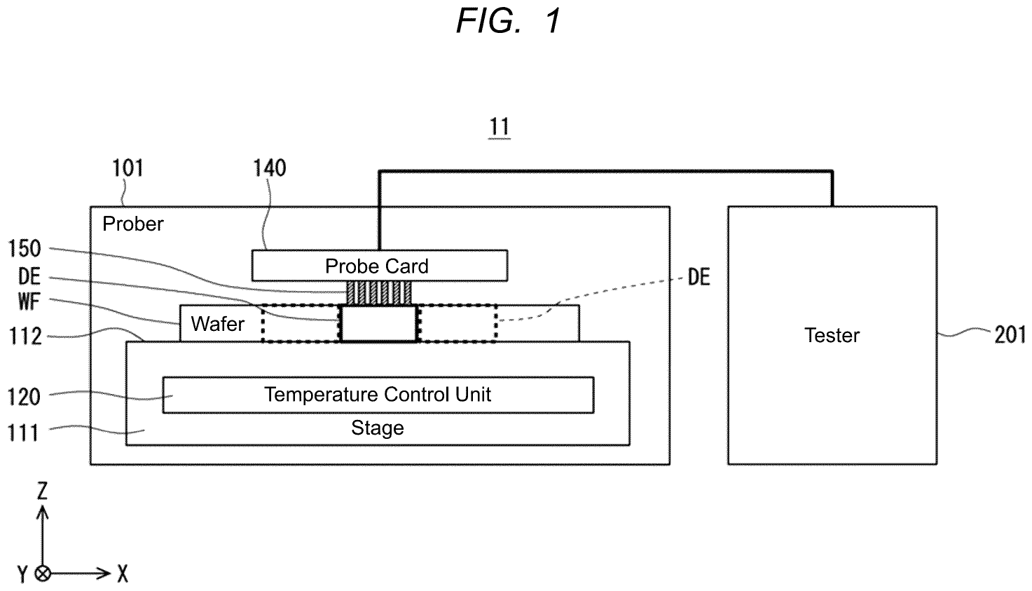

FIG. 1 is a configuration diagram illustrating the inspection apparatus 11 for semiconductor device DE according to the comparative example. As shown in FIG. 1, the inspection apparatus 11 includes a prober 101 and a tester 201. The prober 101 includes a stage 111 and a probe card 140. The stage 111 has a temperature control unit 120. The probe card 140 has probes 150. The inspection apparatus 11 inspects the semiconductor device DE formed on the wafer WF. The wafer WF may have multiple semiconductor devices DE formed on it. The inspection apparatus 11 inspects each semiconductor device DE. In the following description, it is assumed that multiple semiconductor devices DE are formed on the wafer WF, but at least one semiconductor device DE may be formed on the wafer WF. The wafer WF may be referred to as a sample. Note that the sample is not limited to the wafer WF as long as the semiconductor device DE is formed, and it may be a semiconductor chip, printed circuit board, or semiconductor substrate, etc.

The stage 111 holds the wafer WF. The stage 111 has a stage surface 112. The stage 111 places the wafer WF on the stage surface 112.

Here, for the convenience of explaining the inspection apparatus 11, an XYZ orthogonal coordinate system is introduced. For example, the direction perpendicular to the stage surface 112 is the Z-axis direction, and the plane parallel to the stage surface 112 is the XY plane.

The stage 111 may have a suction mechanism such as a suction chuck. The wafer WF may be arranged on stage surface 112 by using the suction mechanism. The stage 111 may have a moving mechanism to change the relative position between the wafer WF and the probes 150. Note that the probe card 140 or the tester 201 may have a moving mechanism to change the relative position between the wafer WF and the probes 150. The moving mechanism can slide in the X-axis direction, Y-axis direction, and Z-axis direction, or can rotate using the X-axis, Y-axis, and Z-axis as rotation axes.

The probe card 140 contacts the semiconductor device DE, which is the inspection target, via the probes 150. This allows the probe card 140 to be electrically coupled with the semiconductor device DE. The probe card 140 is coupled with the tester 201 to transmit information to each other. The tester is provided separately from the prober 101. The probe card 140 applies electrical signals, including power and current from the tester 201, to the semiconductor device DE via the probes 150. Additionally, the probe card 140 can transmit electrical signals from the semiconductor device DE to the tester 201.

The temperature control unit 120 is arranged to be incorporated into the stage 111. By heating or cooling the stage 111, the temperature control unit 120 sets stage 111 to a predetermined temperature.

Next, the operation of the inspection apparatus 11 will be described. First, to set the wafer WF to a predetermined inspection temperature, the stage 111 is set to a predetermined temperature. Specifically, the temperature control unit 120 heats or cools the stage 111 to raise or lower its temperature, ensuring that the wafer WF reaches the inspection temperature. During inspecting the semiconductor device DE, the temperature control unit 120 controls so that the wafer WF maintains a constant inspection temperature. Hereinafter, the semiconductor device DE to be inspected will be referred to as the semiconductor device DE. Once the wafer WF reaches the inspection temperature and the temperature stabilizes, the relative position of the semiconductor device DE and the probe card 140 are adjusted to overlap in the Z-axis direction. For example, by moving the stage 111 horizontally, the semiconductor device DE and the probe card 140 are made to overlap in the Z-axis direction.

After the semiconductor device DE is moved directly below the probe card 140, the relative position in the Z-axis direction between the stage 111 and the probe card 140 is brought closer so that probes 150 of the probe card 140 contact the terminals of the semiconductor device DE. Electrical coupling is achieved when probes 150 contact the terminals of the semiconductor device DE. When the inspection of the semiconductor device DE begins, electrical signals, including power and current, are supplied from the tester 201 to the semiconductor device DE. In this way, predetermined electrical signals are input to the semiconductor device DE from the tester 201 via the probe card 140.

The electrical signals from the semiconductor device DE are output to the tester 201 via the probe card 140. In this manner, the tester 201 receives the output from the semiconductor device DE. The tester 201 stores expected values of the output of the semiconductor device DE corresponding to the input predetermined electrical signals. By comparing the expected values with the actual output values, the tester 201 determines whether the semiconductor device DE is operating correctly or incorrectly. Thus, tester 201 inspects the quality of the semiconductor device DE.

After the inspection of the semiconductor device DE is completed, the probes 150 of the probe card 140 are separated from the terminals of the semiconductor device DE, and the stage 111 is moved horizontally to inspect the next semiconductor device DE.

### Problem Recognized by Inventors

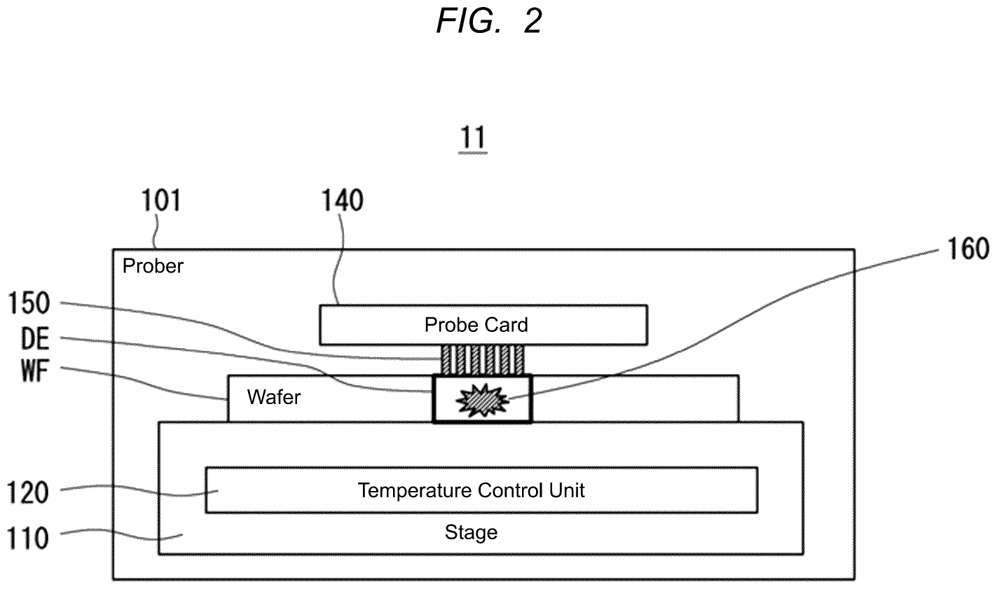

FIG. 2 illustrates a problem recognized by the inventors on the inspection apparatus 11 for the semiconductor device DE according to the comparative example. As shown in FIG. 2, one of the problems recognized by the inventors is the non-uniform temperature of the semiconductor device DE. Recently, circuit blocks requiring high power are mounted in the semiconductor device DE, and when these circuit blocks operate, the temperature of the semiconductor device DE rises locally. Here, such a temperature rise is referred to as self-heating 160. The inspection apparatus 11 of the comparative example attempts to make the temperature of the semiconductor device DE uniform by keeping the temperature of the stage 110 constant. However, in the inspection apparatus 11, it is difficult to follow local temperature rises. Therefore, temperature distribution disturbances occur inside the semiconductor device DE. This local temperature fluctuation adversely affects the measurement temperature in the inspection environment of the semiconductor device DE, hindering accurate inspection. Therefore, it may be not possible to improve the inspection accuracy of the semiconductor device.

### First Embodiment

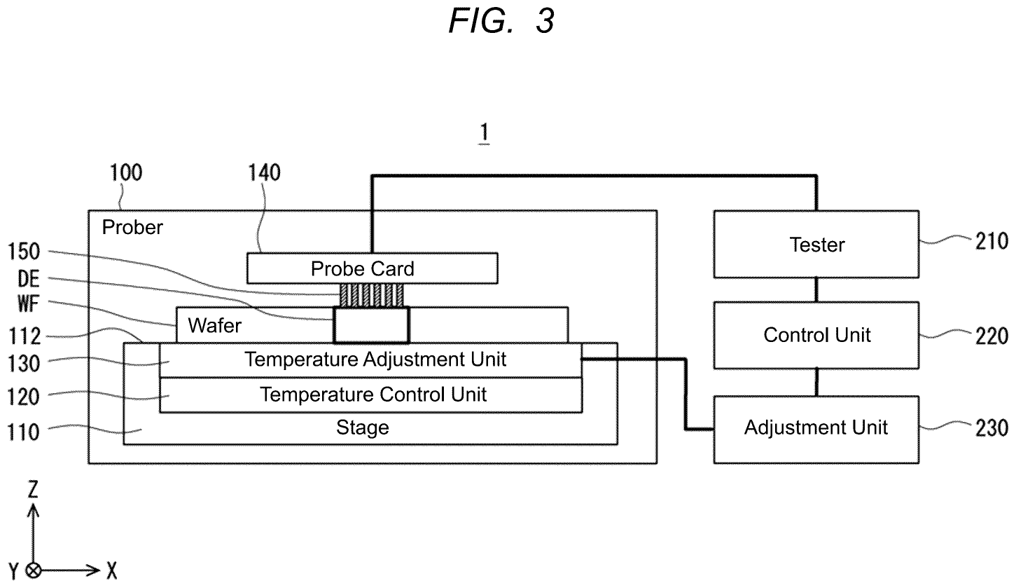

Next, an inspection apparatus for the semiconductor device DE according to the first embodiment will be described. FIG. 3 illustrates a configuration diagram of the inspection apparatus 1 for the semiconductor device DE according to the first embodiment. As shown in FIG. 3, the inspection apparatus 1 of the present embodiment includes a prober 100, a tester 210, a control unit 220, and an adjustment unit 230. The prober 100 includes stage 110 and a probe card 140. The stage 110 has a temperature control unit 120 and a temperature adjustment unit 130. The probe card 140 has probes 150. The inspection apparatus 1 of the present embodiment inspects the semiconductor device DE formed on the wafer WF, similar to the inspection apparatus 11 of the comparative example. The inspection apparatus 1 of the present embodiment differs from the inspection apparatus 11 of the comparative example in that it includes a temperature adjustment unit 130 in the stage 110 of the prober 100. Additionally, the inspection apparatus 1 of the present embodiment differs from the inspection apparatus 11 of the comparative example in that it includes a control unit 220 and an adjustment unit 230.

The stage 110 holds the wafer WF, which serves as a sample. The stage 110 has a stage surface 112. The stage 110 places the wafer WF, which includes at least one semiconductor device DE, on stage surface 112.

The temperature control unit 120 is a different component from the temperature adjustment unit 130. The temperature control unit 120 is arranged to be incorporated into the stage 110. The temperature control unit 120 is positioned on the −Z axis side of stage 110 relative to the temperature adjustment unit 130. The temperature control unit 120 performs at least one of heating and cooling to set the temperature of stage 110 to a predetermined value. This allows the temperature control unit 120 to set the stage 110 to a predetermined temperature. Although not shown, the temperature control unit 120 may be coupled with the control unit 220 that transmits information to the temperature control unit 120. The control unit 220 may control the temperature control unit 120.

The temperature adjustment unit 130 is a different component from the temperature control unit 120. The temperature adjustment unit 130 is arranged to be incorporated into the stage 110. The temperature adjustment unit 130 is positioned on the +Z axis side of stage 110 relative to the temperature control unit 120. In other words, the temperature adjustment unit 130 is positioned between the temperature control unit 120 and the stage surface 112. The temperature adjustment unit 130 adjusts the temperature of the semiconductor device DE formed on the wafer WF. For example, to smoothly perform heat absorption and heat dissipation of the semiconductor device DE by the temperature adjustment unit 130, it is preferable that the temperature adjustment unit 130 is in close contact with the body of the stage 110 and that the thermal resistance between the body of the stage 110 and the temperature adjustment unit 130 is extremely small. The wafer WF is placed on the temperature adjustment unit 130. Therefore, the surface on the +Z axis side of the temperature adjustment unit 130 may also be the stage surface 112. It is preferable that the wafer WF is suctioned onto the temperature adjustment unit 130. With such a configuration, the temperature adjustment unit 130 efficiently adjusts the temperature of the semiconductor device DE formed on the wafer WF.

The wafer WF, which serves as a sample, may have multiple semiconductor devices DE formed on it. The probes 150 of the probe card 140 contact the terminals of the semiconductor device DE. This establishes electrical coupling between the probes 150 and the terminals of the semiconductor device DE. In the inspection of the semiconductor device DE, the semiconductor device DE may be inspected one by one, or multiple semiconductor devices DE may be inspected in parallel. In this case, multiple probes 150 may contact the terminals of multiple semiconductor devices DE.

When the inspection of the semiconductor device DE begins, electrical signals, including power and current, are input from the tester 210 to the semiconductor device DE, and predetermined electrical signals are input to the semiconductor device DE from the tester 210 via the probe card 140. The electrical signals from the semiconductor device DE are output to the tester 210 via the probe card 140. The tester 210 receives the output from the semiconductor device DE. In this way, tester 210 inspects the semiconductor device by applying electrical signals to the semiconductor device DE.

The control unit 220 is coupled with the tester 210 and the adjustment unit 230. The control unit 220 controls the operation of the tester 210. Additionally, the control unit 220 controls the operation of adjustment unit 230. The adjustment unit 230 is coupled with the temperature adjustment unit 130. The adjustment unit 230 adjusts the operation of the temperature adjustment unit 130. Specifically, the adjustment unit 230 adjusts the output of the temperature adjustment unit 130. The control unit 220 controls the adjustment unit 230 so that the adjustment unit 230 outputs appropriate values.

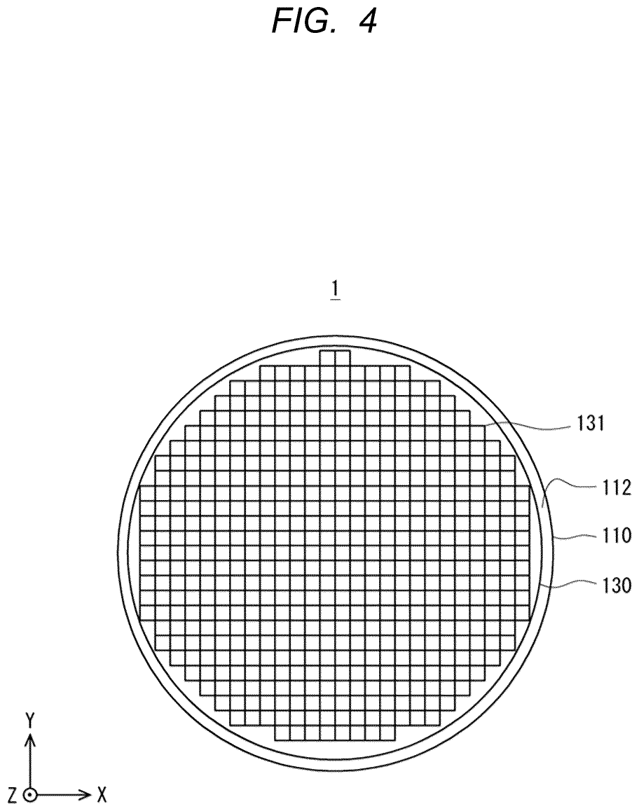

FIG. 4 is a plan view illustrating the temperature adjustment unit 130 in the inspection apparatus 1 for the semiconductor device DE according to the first embodiment. As shown in FIG. 4, the temperature adjustment unit 130 includes a plurality of temperature adjustment elements 131. The temperature adjustment elements 131 are arranged in a plane parallel to the stage surface 112 of the stage 110. For example, the temperature adjustment elements 131 are arranged in a matrix form along the X-axis and Y-axis directions without gap. Each temperature adjustment element 131 operates under the control of the adjustment unit 230. In other words, the adjustment unit 230 adjusts the output of each temperature adjustment element 131. This allows each temperature adjustment element 131 to be individually controlled by the adjustment unit 230. Therefore, the temperature adjustment unit 130 may include at least one temperature adjustment element 131 that is controlled differently from the other temperature adjustment elements 131. Each temperature adjustment element 131, for example, has a rectangular structure with a side length of approximately 1 mm to 5 mm, but is not necessarily limited to this. Each temperature adjustment element 131 adjusts the temperature of a local area of the semiconductor device DE.

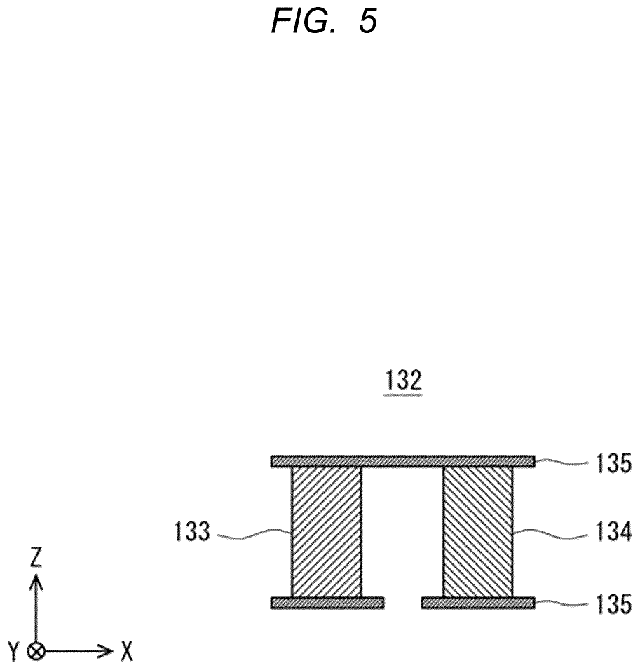

FIG. 5 is a diagram illustrating the temperature adjustment element 131 in the inspection apparatus 1 for the semiconductor device DE according to the first embodiment. As shown in FIG. 5, the temperature adjustment element 131 may include a Peltier element 132. The Peltier element 132 is configured with an N-type semiconductor 133 and a P-type semiconductor 134 sandwiched by metal 135. Specifically, the N-type semiconductor 133 and the P-type semiconductor 134 are prismatic and extend in the Z-axis direction. The ends on the +Z-axis side of the N-type semiconductor 133 and the P-type semiconductor 134 are coupled to each other by one metal 135. The ends on the −Z-axis side of the N-type semiconductor 133 and the P-type semiconductor 134 are connected to separate metals 135, respectively.

By passing current from metal 135 of the −Z-axis side end of the P-type semiconductor 134 to the metal 135 of the −Z-axis side end of the N-type semiconductor 133, or vice versa, it is possible to dissipate heat or absorb heat at metal 135 of the +Z-axis side. The amount of heat absorption or dissipation is determined by the temperature difference between the metal 135 of the +Z-axis side and the metal 135 of the −Z-axis side, and the magnitude of the current flowing (also referred to as current value).

It should be noted that the temperature adjustment element 131 is not limited to those including the Peltier element 132. The temperature adjustment element 131 can be any device capable of adjusting the temperature of a local area of the semiconductor device DE, such as a heat sink with capillaries through which coolant flows, small connecting rods attached to a heat sink, or small heaters.

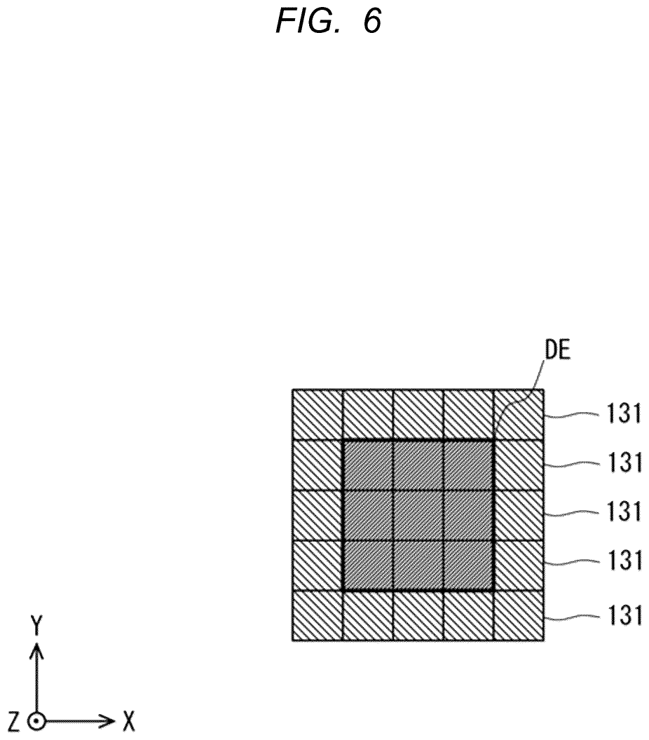

FIG. 6 is a diagram illustrating the positional relationship between the temperature adjustment element 131 and the semiconductor device DE in the inspection apparatus 1 for the semiconductor device DE according to the first embodiment. As shown in FIG. 6, the size of the temperature adjustment element 131 may be sufficiently small compared to the size of the semiconductor device DE. For example, the semiconductor device DE may be positioned on a plurality of temperature adjustment elements 131. For instance, when viewed from a direction perpendicular to the stage surface 112, the size of each temperature adjustment element 131 in the plane parallel to the stage surface 112 may be less than or equal to the size of the semiconductor device DE in the plane parallel to the stage surface 112. In the figure, as an example, the size of one semiconductor device DE corresponds to the size of nine temperature adjustment elements 131. It is not necessary for an integer number of temperature adjustment elements 131 to correspond to one semiconductor device DE without gaps; for example, one semiconductor device DE may correspond to nine and a half temperature adjustment elements 131.

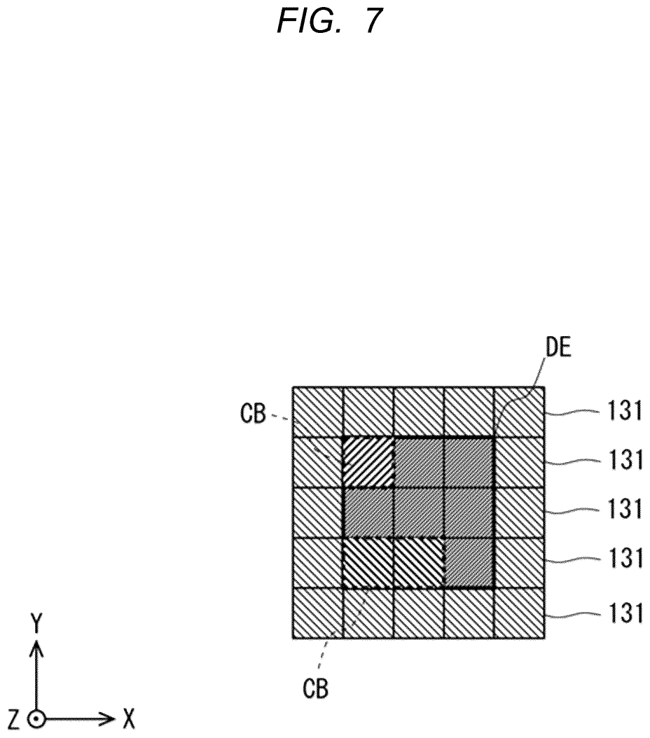

FIG. 7 is a diagram illustrating the positional relationship between the temperature adjustment element 131 and the circuit block CB in the inspection apparatus 1 for the semiconductor device DE according to the first embodiment. As shown in FIG. 7, the semiconductor device DE may include a plurality of circuit blocks CB. The circuit block CB includes functional blocks such as a CPU (Central Processing Unit), GPU (Graphics Processing Unit), FPGA (Field-programmable Gate Array), etc. The size of the temperature adjustment element 131 may be smaller compared to the size of the circuit block CB. For example, the circuit block CB may be positioned on multiple temperature adjustment elements 131. For instance, when viewed from a direction perpendicular to the stage surface 112, the size of each temperature adjustment element 131 in the plane parallel to the stage surface 112 may be less than or equal to the size of the circuit block CB in the plane parallel to the stage surface 112. The probes 150 of probe card 140 may contact the terminals of the circuit block CB. The tester 210 may inspect the circuit block CB by applying electrical signals to it.

The control unit 220 determines the inspection item of the semiconductor device DE when inspecting the semiconductor device DE. Additionally, the control unit 220 identifies the circuit block CB to which electrical signals, including power and current, are applied. Then, the control unit 220 identifies the temperature adjustment element 131 associated with the identified circuit block CB. For example, the control unit 220 determines the inspection item according to programs and tables and identifies the circuit block CB to be inspected, which is also referred to the inspection target circuit block CB, based on the inspection item and the temperature adjustment element 131.

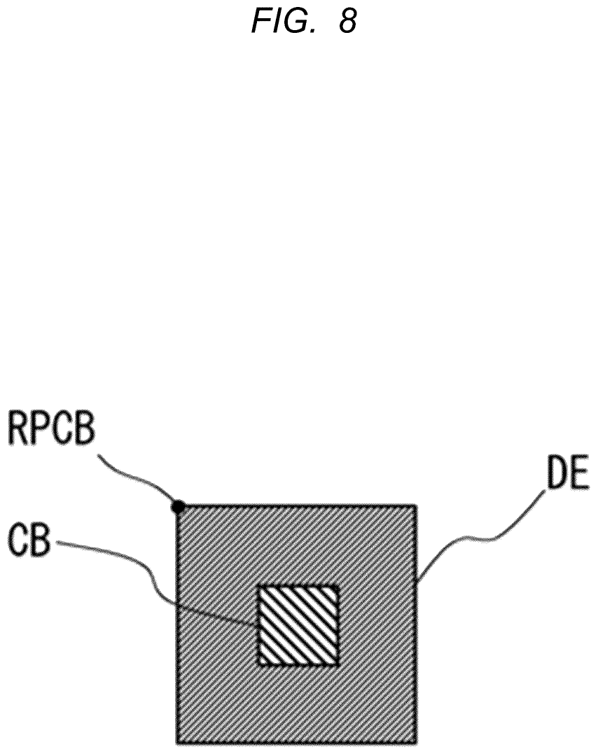

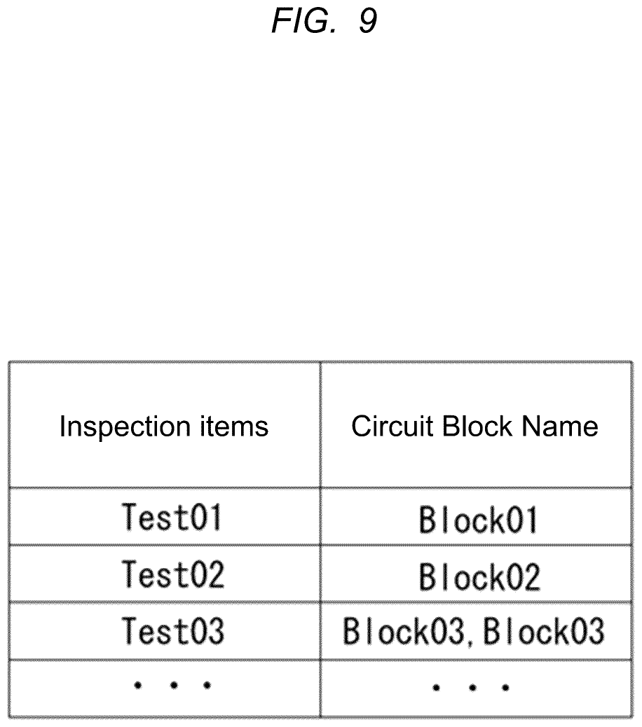

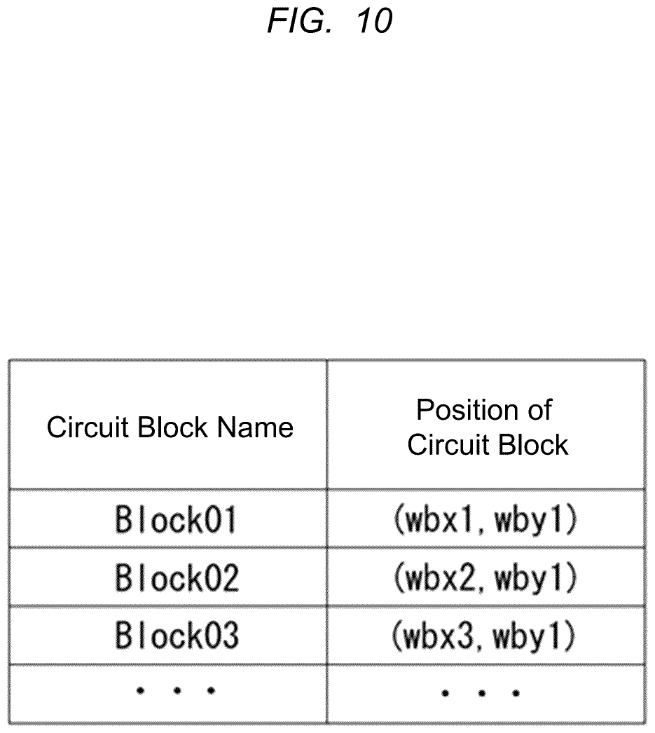

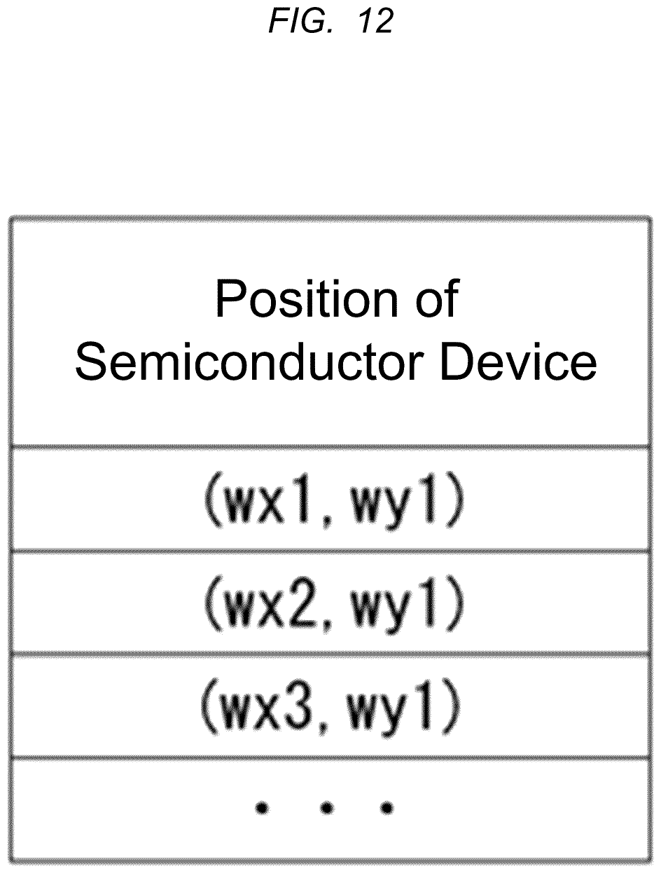

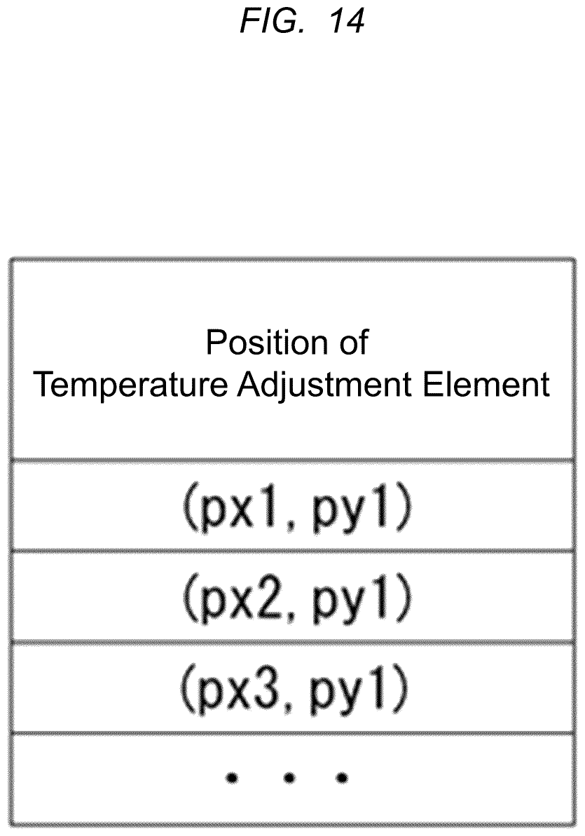

FIG. 8 is a plan view illustrating the position of the circuit block CB in the semiconductor device DE in the inspection apparatus according to the first embodiment. FIG. 9 is a diagram illustrating the correspondence between the inspection items and the circuit blocks CB in the inspection apparatus for the semiconductor device DE according to the first embodiment. FIG. 10 is a diagram illustrating the correspondence between the circuit block CB and the position of the circuit block CB in the inspection apparatus for the semiconductor device DE according to the first embodiment. Tables showing the correspondence between the inspection items and the circuit blocks CB to be inspected based on the inspection item in FIG. 9, and the correspondence between the circuit block CB and the position of the circuit block CB in FIG. 10, may be stored in control unit 220 or in the storage section 240 described later. The same applies to the tables in FIGS. 12 and 14.

As shown in FIGS. 8 to 10, to identify the temperature adjustment element 131 corresponding to the circuit block CB within the semiconductor device DE under inspection, the correspondence prepared in advance, such as tables, is utilized. For example, by using the correspondence between the inspection items and the circuit blocks CB in FIG. 9, the circuit block CB to be inspected is identified. The position of the identified circuit block CB within the semiconductor device DE is specified by using the correspondence between the circuit block CB and the position of the circuit block CB within the semiconductor device DE in FIG. 10. The position of the circuit block CB is specified, for example, by the coordinate position based on the predetermined reference position RPCB (e.g., the upper left corner) of the semiconductor device DE in FIG. 8.

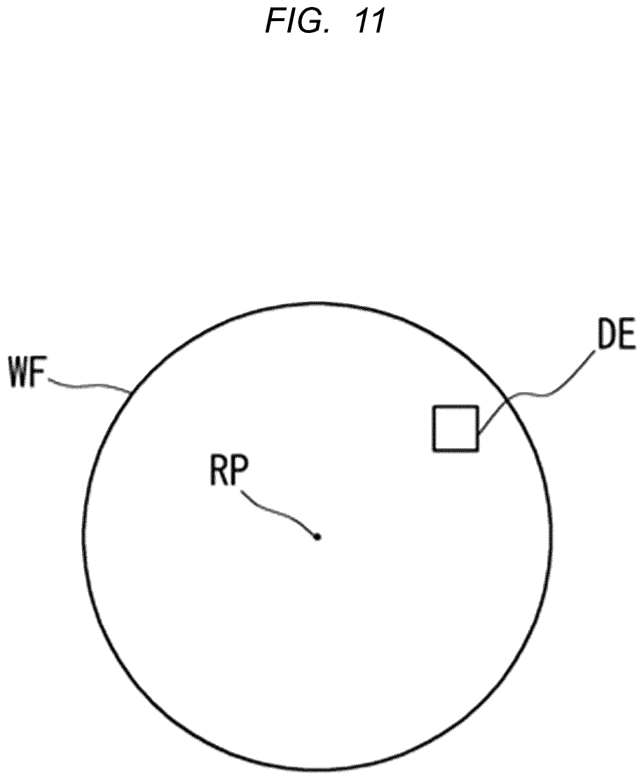

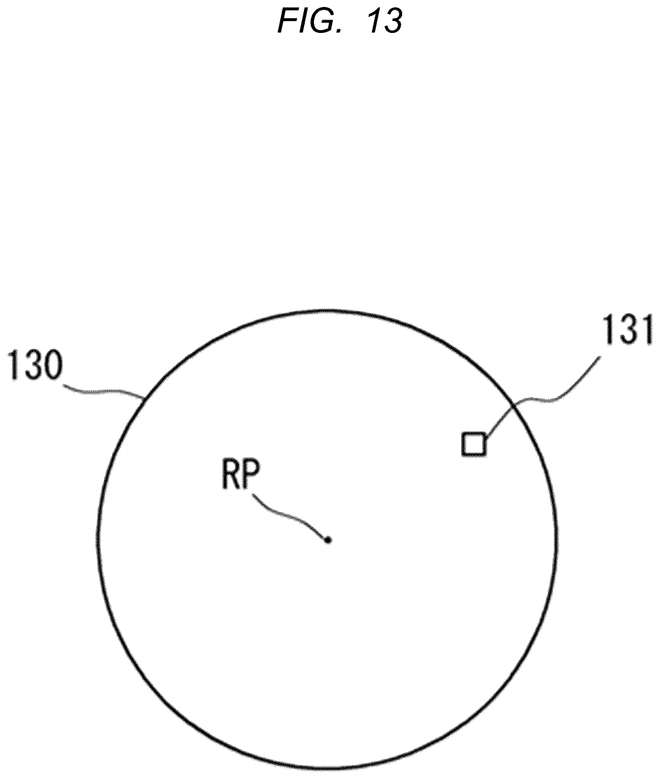

FIG. 11 is a plan view illustrating the position of the semiconductor device DE on the wafer WF in the inspection apparatus for the semiconductor device DE according to the first embodiment. FIG. 12 is a diagram illustrating the position of the semiconductor device DE on the wafer WF in the inspection apparatus for the semiconductor device DE according to the first embodiment. FIG. 13 is a plan view illustrating the position of the temperature adjustment element 131 in the temperature adjustment unit 130 in the inspection apparatus for the semiconductor device DE according to the first embodiment. FIG. 14 is a diagram illustrating the position of the temperature adjustment element 131 in the temperature adjustment unit 130 in the inspection apparatus for the semiconductor device DE according to the first embodiment.

As shown in FIGS. 11 to 14, by using the position from the reference position RP on stage 110 for each of the semiconductor device DE and the temperature adjustment element 131, the temperature adjustment element 131, associated with the circuit block CB within the semiconductor device DE can be identified. In this way, the Peltier element 132 corresponding to the circuit block CB under inspection can be selected and driven.

The control unit 220 controls the operation of tester 210 to have tester 210 inspect the semiconductor device DE. Specifically, the control unit 220 allows the tester 210 to inspect by applying electrical signals to the semiconductor device DE. Based on the results of tester 210 inspecting the semiconductor device DE by applying electrical signals, the control unit 220 controls the adjustment unit 230.

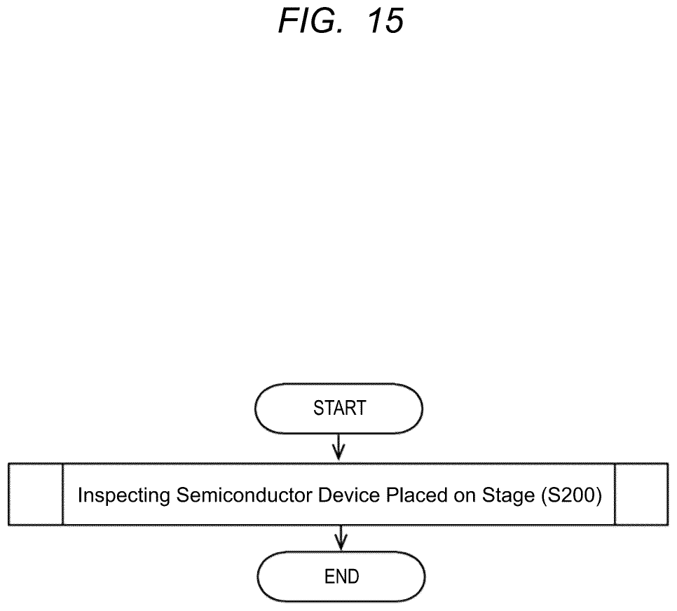

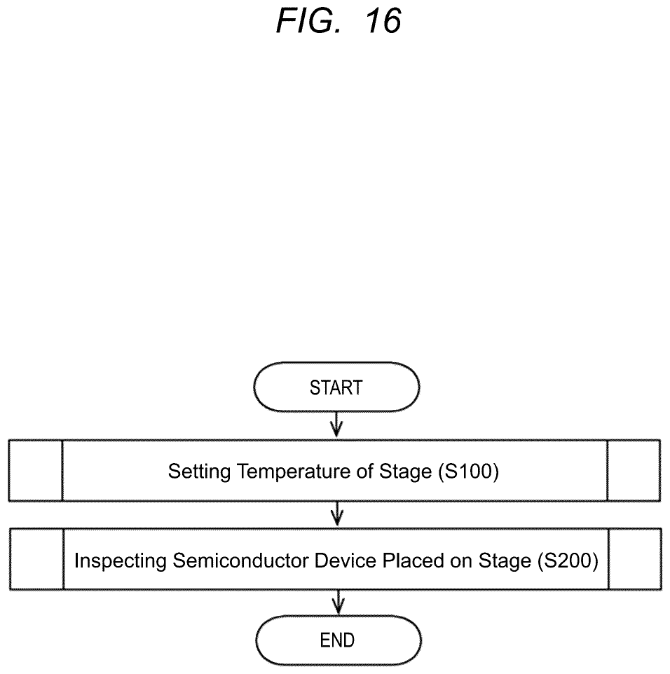

Next, the operation of the inspection apparatus 1 for the semiconductor device DE according to the first embodiment will be described using a flowchart. FIGS. 15 and 16 are flowchart diagrams illustrating the inspection method as the operation of the inspection apparatus for the semiconductor device DE according to the first embodiment. As shown in FIGS. 15 and 16, the inspection method for the semiconductor device DE in this embodiment includes a step S200 of inspecting the semiconductor device DE placed on the stage 110. Note that a step S100 of setting the temperature of the stage 110 to a predetermined value may be included before step S200.

The stage 110 may have a temperature control unit 120 that is different from the temperature adjustment unit 130. In step S100, the temperature control unit 120 may perform at least one of heating and cooling so that the temperature of the stage 110 reaches a predetermined value. For example, the control unit 220 may control the temperature control unit 120 to set the stage 110 to a predetermined temperature. Subsequently, the control unit 220 continuously controls the temperature control unit 120 so that the temperature of stage 110 remains constant.

In step S200, the control unit 220 sequentially inspects the semiconductor devices DE on the wafer WF placed on the stage 110. Here, the stage 110 includes a temperature adjustment unit 130 with a plurality of temperature adjustment elements 131. The temperature adjustment elements 131 are arranged in a plane parallel to the stage surface 112 of stage 110. The size of each temperature adjustment element 131 on the stage surface 112 is less than or equal to the size of the semiconductor device DE on the stage surface 112.

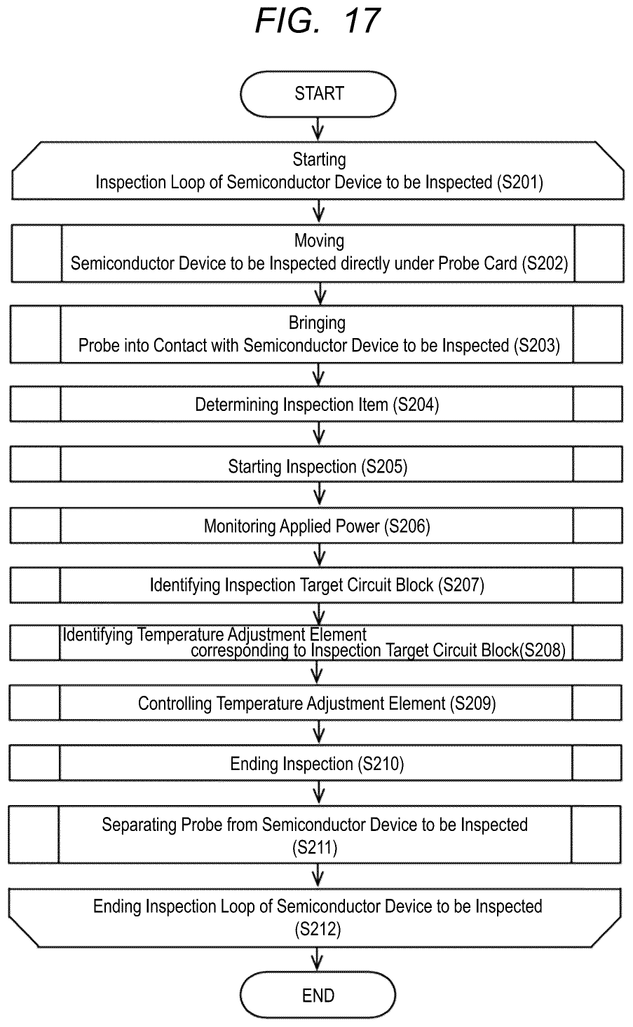

FIG. 17 is a flowchart illustrating the inspection method for the semiconductor device DE according to the first embodiment, showing the inspection of the semiconductor device DE as an example. As shown in FIG. 17, the step S200 of inspecting the semiconductor device DE includes the following steps S201 to S212. That is, the step S200 of inspecting the semiconductor device DE includes the step S201 of starting the inspection loop of the semiconductor device DE to be inspected, the step S202 of moving the semiconductor device DE to be inspected directly under the probe card 140, and the step S203 of bringing the probe 150 into contact with the semiconductor device DE to be inspected. Furthermore, the step S200 of inspecting the semiconductor device DE includes the step S204 of determining the inspection item, the step S205 of starting the inspection, the step S206 of monitoring the applied power, the step S207 of identifying the circuit block to be inspected, and the step S208 of identifying the temperature adjustment element 131 corresponding to the circuit block to be inspected. Additionally, the step S200 of inspecting the semiconductor device DE includes the step S209 of controlling the temperature adjustment element 131, the step S210 of ending the inspection, the step S211 of separating the probe 150 from the semiconductor device DE to be inspected, and the step S212 of ending the inspection loop of the semiconductor device DE to be inspected.

In step S201, among the multiple semiconductor devices DE formed on the wafer WF, the semiconductor device DE to be inspected is identified. For example, the control unit 220 identifies the semiconductor device DE to be inspected among the multiple semiconductor devices DE formed on the wafer WF. If all the semiconductor devices DE to be inspected have been inspected, there is no semiconductor device DE to be inspected, so the series of operations is terminated.

Next, in step S202, the semiconductor device DE to be inspected is moved directly under the probe card 140, for example, the stage 110 is moved horizontally. For example, control unit 220 controls the stage 110 to move horizontally so that the semiconductor device DE to be inspected is directly under the probe card 140. Alternatively, the probe card 140 may be moved horizontally instead of moving the stage 110.

Next, in step S203, after the semiconductor device DE is placed directly under probe card 140, probe card 140 and the wafer WF are brought close together, and probes 150 of probe card 140 contact the terminals of the semiconductor device DE.

For example, by control of the control unit 220, the semiconductor device DE is placed directly under the probe card 140, then the probe card 140 and the wafer WF are brought close together, and probes 150 of the probe card 140 contact with the terminals of the semiconductor device DE. By contacting probe 150 with the semiconductor device DE, both are electrically coupled.

Next, in step S204, the inspection item of the semiconductor device DE is determined. For example, the control unit 220 determines the inspection item of the semiconductor device DE to be inspected.

Next, in step S205, according to the determined inspection item, the control unit 220 issues instructions to the tester 210. As a result, the tester 210 inspects the semiconductor device DE by applying electrical signals, including power and current, to the semiconductor device DE to be inspected.

Next, in step S206, during the inspection, the tester 210 continuously measures the electrical signals applied to the semiconductor device DE to be inspected and sends the measurement results to control unit 220. For example, the tester 210 may continuously observe the supply power amount in the electrical signals and send its value to the control unit 220.

In step S207, during the inspection, various circuit blocks CB in the semiconductor device DE to be inspected are driven. The tester 210 sends information to the control unit 220 about which circuit block CB is being driven at that time, i.e., which circuit block CB is consuming power. In other words, the tester 210 inspects the circuit block CB by applying electrical signals to it. Here, the tester 210 does not necessarily need to identify the name of circuit block CB. The tester 210 may send only information that can identify the circuit block CB to the control unit 220. The control unit 220 may specifically identify the name of circuit block CB. That is, the control unit 220 identifies the circuit block CB to which electrical signals are applied. The control unit 220 identifies the position of the circuit block CB by matching the information of the semiconductor device DE to be inspected, which includes information that can identify the circuit block CB sent from the tester 210, with the information such as the table shown in FIGS. 8 to 14, thereby identifying the position of the circuit block CB on the wafer WF and identifies the position of the temperature adjustment element 131 corresponding to the position of the circuit block CB.

In this way, the control unit 220 recognizes where the identified circuit block CB is located in the semiconductor device DE to be inspected and where the circuit block CB to be inspected is located within the wafer WF. This allows the position of the circuit block CB within the wafer WF to be identified.

Next, in step S208, the temperature adjustment element 131 adjacent to the circuit block CB is identified. Specifically, the control unit 220 identifies the temperature adjustment element 131 located directly under the circuit block CB to which electrical signals are applied. The temperature adjustment element 131 is not necessarily limited to one. Depending on the position of the circuit block CB, a plurality of the temperature adjustment elements 131 may be identified. In this way, the control unit 220 identifies the temperature adjustment element 131 associated with the identified circuit block CB.

Next, in step S209, the temperature adjustment element 131 is driven to absorb the same amount of heat generated in the semiconductor device DE to be inspected by the applied electrical signals (supplied power) using the identified temperature adjustment element 131. This operation is performed by instructions from the control unit 220 to the adjustment unit 230. Specifically, the control unit 220 identifies the temperature adjustment element 131 to be driven and instructs the adjustment unit 230 on the output to the identified temperature adjustment element 131. The adjustment unit 230 drives the temperature adjustment element 131 according to the instructions from the control unit 220. Even if there are multiple temperature adjustment elements 131, the control unit 220 instructs the adjustment unit 230 to drive each temperature adjustment element 131 so that the heat generated in the semiconductor device DE to be inspected is absorbed by multiple temperature adjustment elements 131. In this way, the control unit 220 controls the adjustment unit 230 that adjusts each temperature adjustment element 131. The control unit 220 controls the adjustment unit 230 to individually adjust the output to each temperature adjustment element 131. This allows at least one temperature adjustment element 131 to be controlled differently from other temperature adjustment elements 131 during the step of inspecting the semiconductor device. In this case, the temperature adjustment unit 130 may include at least one of the temperature adjustment element 131 that is controlled differently from other temperature adjustment elements 131. The adjustment unit 230 adjusts the output to each temperature adjustment element 131 by controlling the amount of current applied to each temperature adjustment element 131. The above operation is performed at regular time intervals, for example, between 10 ns and 10 ms. Although examples of time intervals are given, it is preferable to narrow the time intervals as much as possible.

In step S210, the process from step S206 to step S209 is repeatedly performed until the inspection content, including the current and power in the electrical signals applied to the semiconductor device DE to be inspected, is completed.

In step S211, after the inspection items of the semiconductor device DE to be inspected are completed, the probe card 140 and the semiconductor device DE to be inspected are separated. If the inspection of all semiconductor devices DE to be inspected is not completed, the process returns to step S201. If the inspections of all semiconductor devices DE to be inspected is completed, the series of processes is terminated.

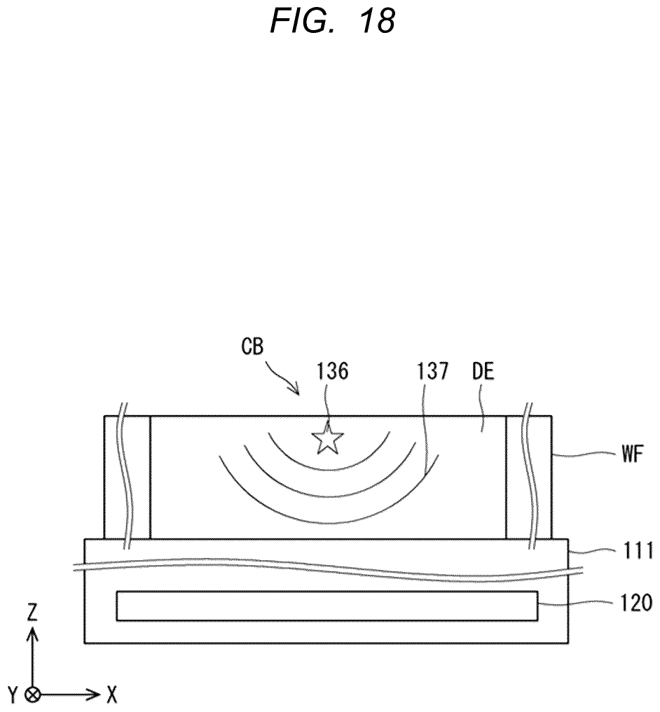

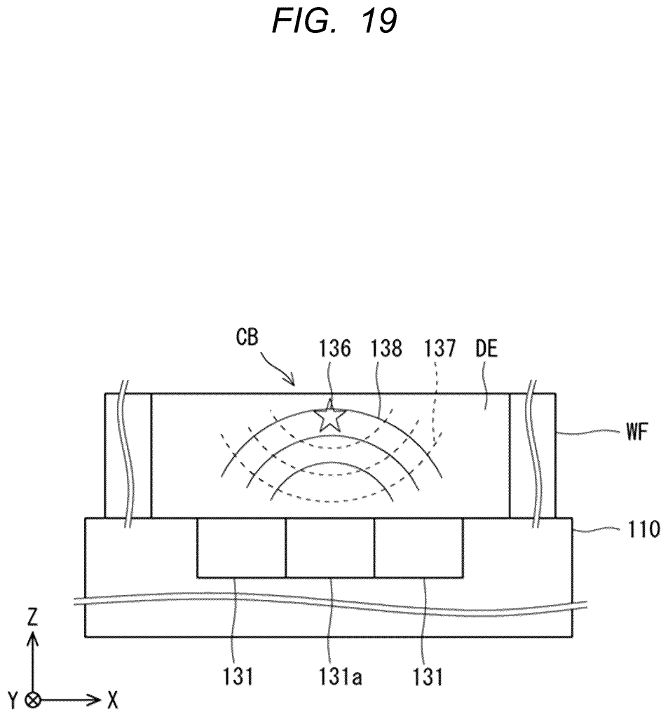

Next, the effects of this embodiment will be described in comparison with the comparative example. FIG. 18 is a diagram illustrating the circuit block of the semiconductor device DE in the inspection apparatus according to the comparative example. FIG. 19 is a diagram illustrating the circuit block of the semiconductor device DE in the inspection apparatus according to the first embodiment.

As shown in FIGS. 18 and 19, the semiconductor device DE to be inspected is formed on the wafer WF. The thickness of the wafer WF is approximately 0.7 mm, for example. When the circuit block CB within the semiconductor device DE operates, it generates heat. Consequently, the temperature of the circuit block CB propagates through the wafer WF via thermal conduction. As illustrated in FIG. 18, this resembles the propagation of waves originating from the heat-generating point 136 (indicated by a star). The heat generated by this conduction eventually is dissipated to stage 111. For convenience, this thermal wave is referred to as a heat wave 137.

As shown in FIG. 18, even if the temperature control unit 120 in the stage 111 of the comparative example controls the temperature of the stage 111 to be uniform, there is a certain distance between the heat-generating point 136 and the stage 111, and there is also thermal resistance in the wafer WF. Therefore, the temperature of the heat-generating point 136 becomes higher than the temperature of stage 111. This temperature difference has not been considered problematic until now. However, semiconductor devices DE that consume large amounts of power may not be able to ignore this temperature difference. The difference between the set temperature by the temperature control unit 120 and the actual temperature of the semiconductor device DE has become significant, making accurate inspection difficult. Therefore, improving the inspection accuracy of the semiconductor device DE has become challenging.

Therefore, in this embodiment, as shown in FIG. 19, the temperature adjustment element 131a associated with the heat-generating point 136 is driven. This allows the temperature adjustment element 131a to absorb heat corresponding to the heat generation of the heat-generating point 136. The control unit 220 identifies which circuit block CB of the semiconductor device DE under inspection is operating based on the inspection item being conducted at that time. Additionally, the control unit 220 determines the amount of power being consumed from the information on the tester 210. Furthermore, the control unit 220 identifies the position of the circuit block CB on the wafer WF and the corresponding position of the temperature adjustment element 131 based on information such as the tables shown in FIGS. 8 to 14. Therefore, control unit 220 identifies the position of the temperature adjustment element 131a associated with the circuit block CB from the position of the circuit block CB. Moreover, the control unit 220 drives the temperature adjustment element 131a to perform heat absorption corresponding to the power consumption of the circuit block CB. Therefore, a thermal wave 138 centered around the temperature adjustment element 131a is generated. The thermal wave 138 is in reverse phase to the thermal wave 137 caused by the heat-generating point 136. By canceling out the thermal waves 137 and 138, the temperature rise of the heat-generating point 136 can be mitigated.

In this way, according to this embodiment, the temperature of the semiconductor device DE can be controlled with high precision, thereby improving the inspection accuracy of the semiconductor device DE.

### Second Embodiment

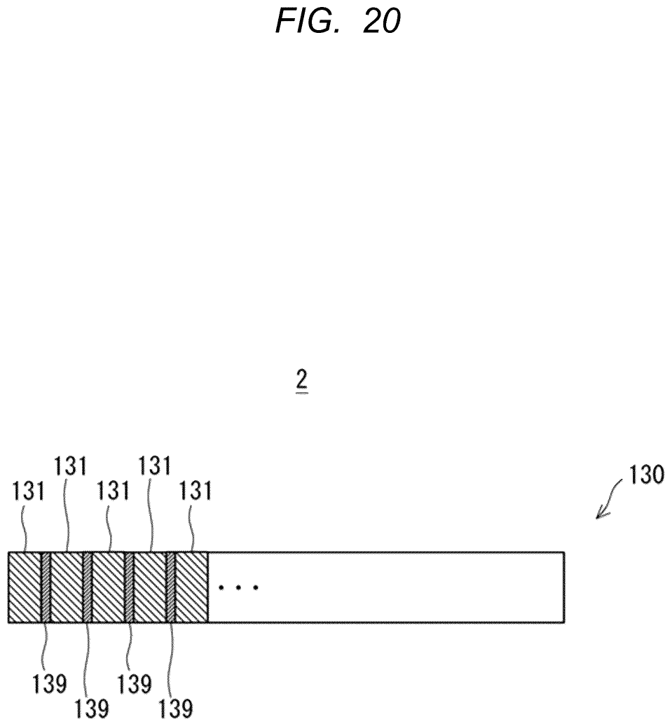

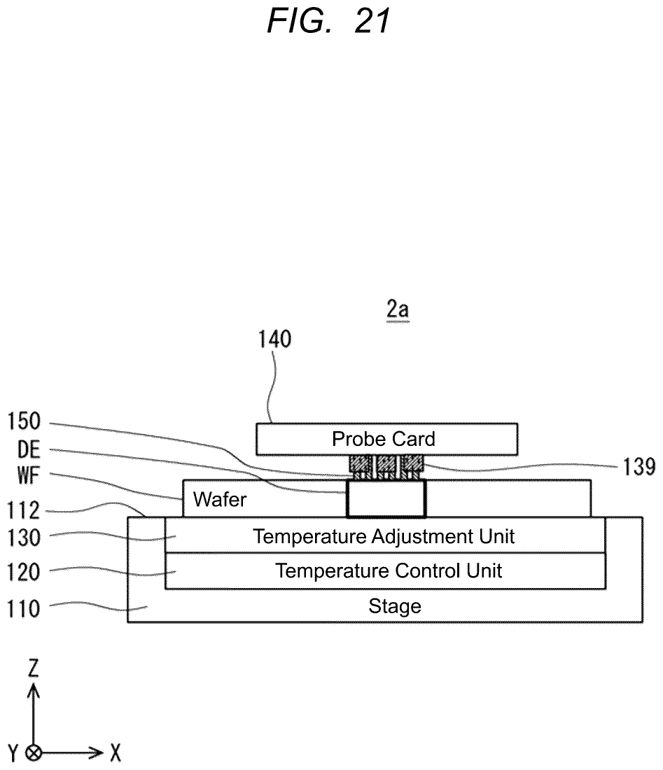

Next, the inspection apparatus for the semiconductor device DE according to the second embodiment will be described. FIGS. 20 and 21 are configuration diagrams illustrating the inspection apparatuses 2 and 2a for the semiconductor device DE according to the second embodiment. As shown in FIGS. 20 and 21, the temperature adjustment unit 130 according to the inspection apparatuses 2 and 2a of this embodiment further includes a temperature sensor 139. The temperature sensor 139 measures the temperature of the semiconductor device DE. The temperature sensor 139 may measure the temperature of the circuit block CB. As shown in FIG. 20, the temperature sensor 139 may be disposed of near the temperature adjustment element 131. For example, multiple temperature sensors 139 may be disposed of near each of the multiple temperature adjustment elements 131. Each temperature sensor 139 may be disposed between adjacent temperature adjustment elements 131. For example, the temperature adjustment elements 131 and the temperature sensors 139 may be alternately arranged in the X-axis and Y-axis directions.

Also, as shown in FIG. 21, the temperature sensor 139 may be disposed of on a probe card 140 closer side to the semiconductor device DE. A plurality of temperature sensors 139 may be disposed of on the probe card 140.

The temperature sensor 139 may be coupled in a state capable of transmitting information to the adjustment unit 230. Additionally, the temperature sensor 139 may be coupled in a state capable of transmitting information to the probe card 140. The temperature sensor 139 measures the temperature controlled by the temperature adjustment element 131. Specifically, the temperature sensor 139 measures the temperature of the semiconductor device DE and the temperature of the circuit block CB. Therefore, the step of inspecting the semiconductor device DE may include the step of measuring the temperature of the semiconductor device DE with the temperature sensor 139, or it may also include the step of measuring the temperature of the circuit block CB with the temperature sensor 139.

The temperature sensor 139 transmits the measurement results to the control unit 220 via the adjustment unit 230. Additionally, the temperature sensor 139 transmits the measurement results to the control unit 220 via the probe card 140 and the tester 210. Based on the measurement results by the temperature sensor 139, the control unit 220 adjusts the control signal to the adjustment unit 230 in order to control the temperature adjustment element 131 when a circuit block CB of the semiconductor device DE to be inspected deviates from the target set temperature range. For example, the control unit 220 instructs the adjustment unit 230 to adjust the amount of current applied to the temperature adjustment element 131. This allows the adjustment unit 230 to adjust the temperature adjustment element 131 to maintain the temperature of the semiconductor device DE and the circuit block CB at the target temperature. In this way, the control unit 220 controls the adjustment unit 230 based on the measurement results of the temperature sensor 139 that measures the temperature of the semiconductor device DE. Additionally, the control unit 220 may control the adjustment unit 230 based on the measurement results of the temperature sensor 139 that measures the temperature of the circuit block CB.

According to this embodiment, since the inspection apparatuses 2 and 2a are equipped with the temperature sensor 139, the actual temperature of the semiconductor device DE and the circuit block CB can be confirmed. Therefore, it is possible to monitor whether the semiconductor device DE and the circuit block CB are maintaining the target set temperature. Unexpected temperature changes can also be detected. Furthermore, by feedback-controlling the temperature adjustment element 131, the performance of maintaining the target set temperature can be improved. Other configurations and effects are included in the description of the first embodiment.

### Third Embodiment

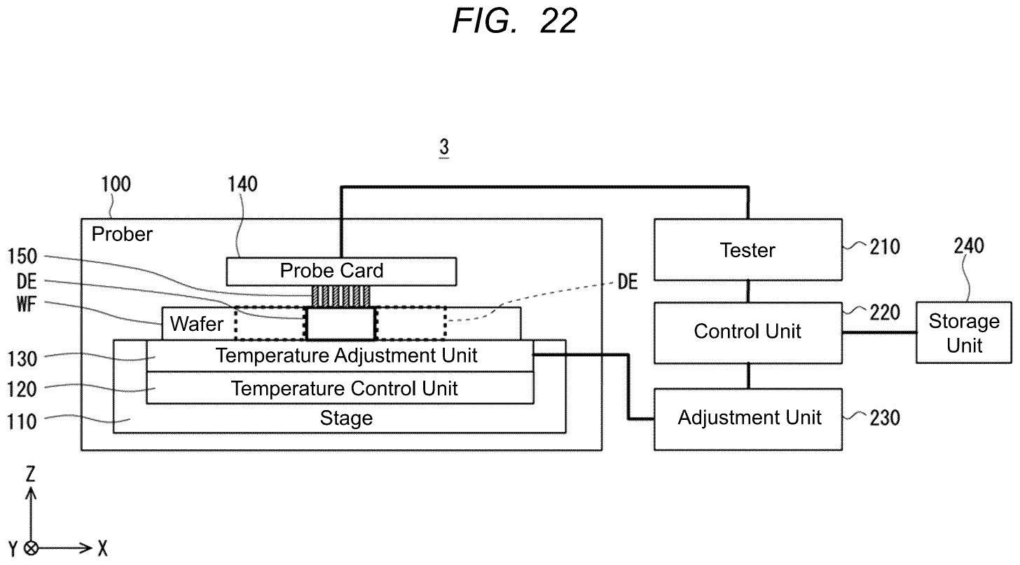

Next, the inspection apparatus for the semiconductor device DE according to the third embodiment will be described. FIG. 22 is a configuration diagram illustrating the inspection apparatus 3 for the semiconductor device DE according to the third embodiment. As shown in FIG. 22, the inspection apparatus 3 further includes a storage unit 240. The storage unit 240 is coupled in a state capable of transmitting information to control unit 220. The storage unit 240 functions as a storage means.

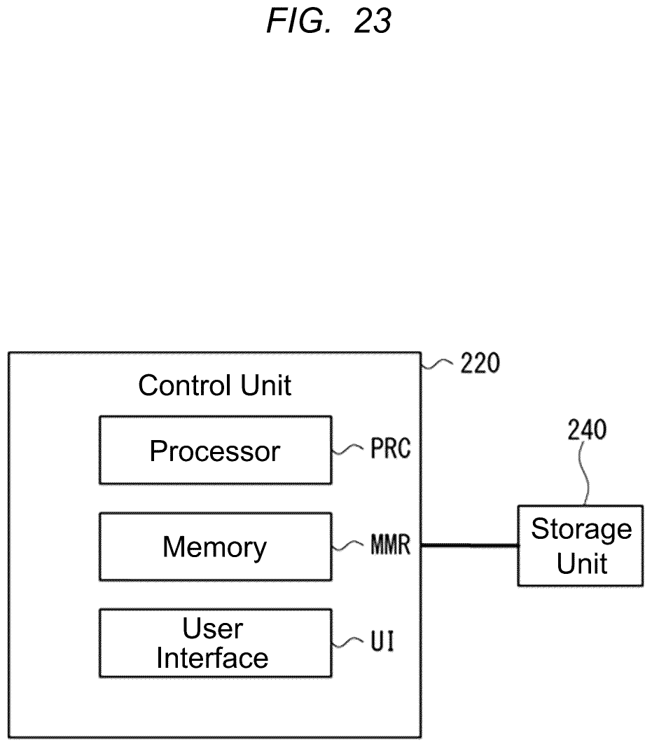

FIG. 23 is a block diagram illustrating the control unit 220 and the storage unit 240 according to the third embodiment. As shown in FIG. 23, the control unit 220 may include information processing devices such as a microcomputer, personal computer, server, tablet, or mobile terminal. The control unit 220 may further include a processor PRC, memory MMR, and a user interface UI. The control unit 220 may also include the storage unit 240.

The storage unit 240 stores programs describing the processes executed by each component of the control unit 220. The processor PRC reads the program from the storage unit 240 into the memory MMR and executes the program. This allows the processor PRC to perform the functions of each component in control unit 220. The user interface UI may include input devices such as a keyboard, mouse, and imaging device, as well as output devices such as a display, printer, and speaker.

Each component of control unit 220 may be a dedicated hardware. Additionally, some or all of the components may be a combination of general-purpose or dedicated circuits, such as the processor PRC, or a combination thereof. These may be configured by a single chip or by multiple chips coupled via a bus. Some or all of the components may be a combination of the aforementioned circuits and programs. The processor PRC may be a CPU, GPU, FPGA, quantum processor (quantum computer control chip), etc.

Additionally, when some or all of the components of the control unit 220 are composed of multiple information processing devices or circuits, the multiple information processing devices or circuits may be collectively or distributively arranged. For example, the information processing devices or circuits may be realized by a client-server system, cloud computing system, etc. and coupled to each other via a communication network NW. The functions of control unit 220 may also be provided in the form of SaaS (Software as a Service).

The storage unit 240 may store information and various data of the semiconductor device DE. The storage unit 240 may include information such as the tables shown in FIGS. 8 to 14. The storage unit 240 may store the power change profile to be applied to the semiconductor device DE by the tester 210 as information of the semiconductor device. Therefore, the information of the semiconductor device DE includes the power change profile to be applied to the semiconductor device DE. The control unit 220 controls the adjustment unit 230 based on the information of the semiconductor device DE stored in the storage unit 240. Specifically, the control unit 220 controls the adjustment unit 230 to adjust the output of each temperature adjustment element 131 based on the power change profile to be applied to the semiconductor device DE. The control unit 220 may control the adjustment unit 230 in advance of the power change profile to be applied to the semiconductor device DE.

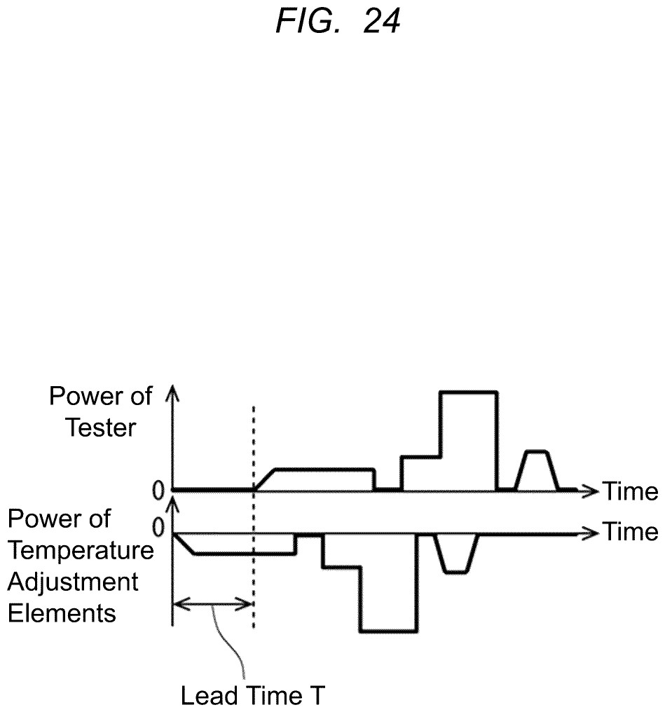

FIG. 24 is a graph illustrating the power change profile applied to the tester 210 and the temperature adjustment elements 131 in the inspection apparatus 3 for the semiconductor device DE according to the third embodiment. The horizontal axis represents time, and the vertical axis represents the power of the tester 210 and the power of the temperature adjustment elements 131. As shown in FIG. 24, the control unit 220 controls tester 210 to apply power to the semiconductor device DE according to a predetermined power change profile. By applying power according to such a power change profile, the tester 210 inspects the semiconductor device DE.

Meanwhile, the control unit 220 controls the adjustment unit 230 to precede the power application to the semiconductor device DE by the tester 210 by a lead time T. Specifically, the control unit 220 controls the adjustment unit 230 to apply power (including current amount) to the temperature adjustment elements 131 according to a power change profile that corresponds to the power change profile applied to the semiconductor device by the tester 210. The adjustment unit 230 drives the temperature adjustment elements 131 ahead of the heat generation in the semiconductor device DE to counteract the heat generated by the power change profile intended to be applied to the semiconductor device DE.

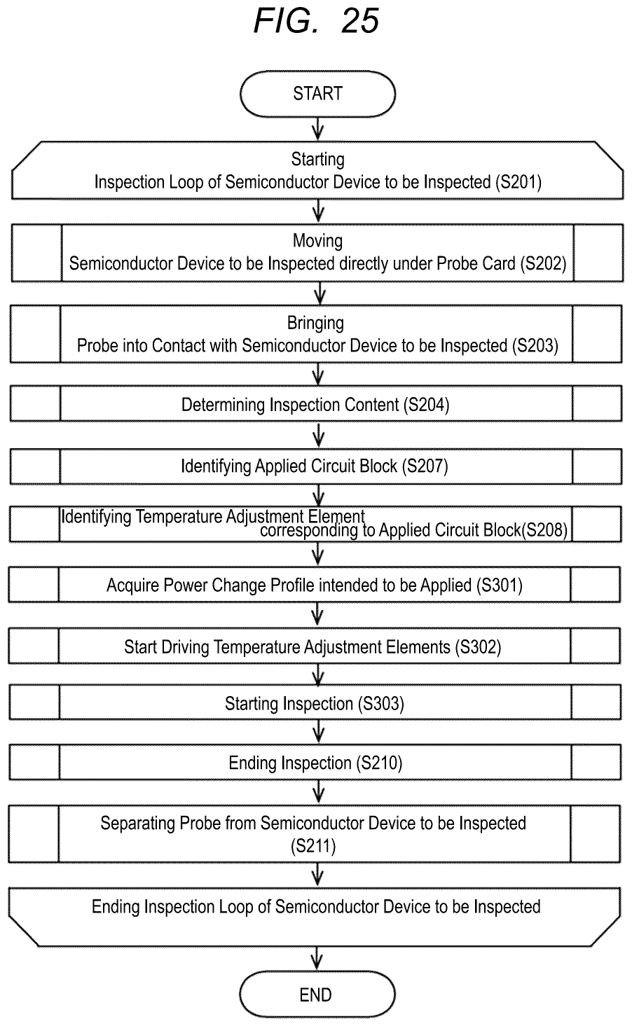

FIG. 25 is a flowchart illustrating the inspection method for the semiconductor device DE according to the third embodiment. As shown in FIG. 25, steps S201 to S204 are the same as the inspection method of the first embodiment. After step S204, steps S207 and S208 are performed.

Subsequently, in step S301, control unit 220 acquires the power change profile intended to be applied to the semiconductor device DE in advance according to the determined inspection content. At this time, the control unit 220 may use the power change profile stored in the storage unit 240 in advance, not only when acquiring the power change profile immediately before the inspection.

In step S302, the control unit 220 uses the power change profile acquired in advance to start driving the temperature adjustment elements 131 in adjustment unit 230 before the power from the tester 210 is applied to the semiconductor device DE. In this way, the control unit 220 controls the adjustment unit 230 to precede the power change profile applied to the semiconductor device DE.

In step S303, the control unit 220 starts applying the power change profile to the semiconductor device DE by the tester 210 after the time has elapsed for the heat absorption by the temperature adjustment elements 131 to reach the heat-generating point 136 of the semiconductor device DE. The subsequent steps are the same as steps S210 to S211 of the first embodiment.

According to this embodiment, the control unit 220 controls the temperature adjustment elements 131 at the corresponding position of the heat-generating point 136 of the semiconductor device DE, preceding to applying the power change profile during the inspection of the semiconductor device DE. This allows the heat generation to be offset before the temperature of the heat-generating point 136 rises, thereby mitigating the temperature increase at the heat-generating point 136. Other configurations and effects are included in the descriptions of the first and second embodiments.

### First Modified Example

Next, the inspection apparatus 3 for the semiconductor device DE according to the first modified example of the third embodiment will be described. The configuration of the inspection apparatus 3 in this modified example is the same as the configuration of the inspection apparatus 3 described above. In this modified example, the control unit 220 instructs the tester 210 to measure the consumed power by applying a dedicated sequence of electrical signals to the semiconductor device DE. Then, the control unit 220 controls the adjustment unit 230 based on the difference between the measured consumed power and the consumed power in the designed semiconductor device DE.

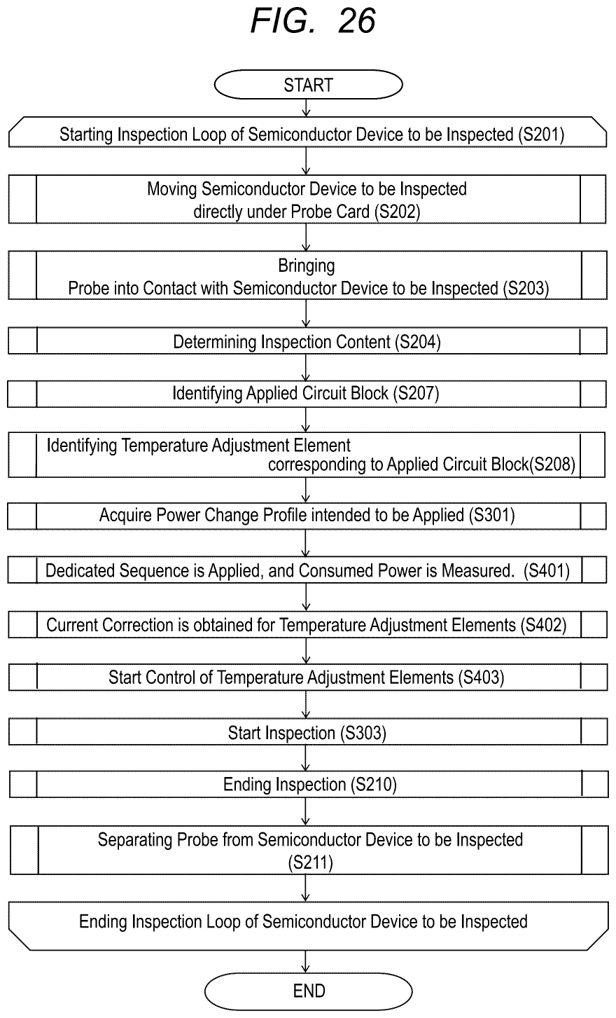

FIG. 26 is a flowchart illustrating the inspection method for the semiconductor device DE according to the first modified example of the third embodiment. As shown in FIG. 26, steps S201 to S301 are the same as in the third embodiment.

In step S401, the electrical signals according to the dedicated sequence are applied to the semiconductor device DE to be inspected, and the consumed power is measured. Alternatively, the consumed power obtained by applying the electrical signals according to the dedicated sequence to a nearby semiconductor device DE in advance may be used. The measurement of consumed power by the dedicated sequence is performed by the control unit 220 controlling the tester 210. Thus, this modified example includes a step of measuring the consumed power by applying the electrical signals according to the dedicated sequence to the semiconductor device DE.

In step S402, if there is a difference between the consumed power obtained by the dedicated sequence and the consumed power obtained by simulation of designing the semiconductor device DE, a correction amount of current equivalent to the difference in consumed power is obtained for the temperature adjustment elements 131, so that the generated heat is offset.

In step S403, the current amount applied to the temperature adjustment elements 131 is controlled, based on the obtained correction amount of current. In other words, the adjustment unit 230 is controlled based on the correction amount of current that compensates for the difference between the measured consumed power and the consumed power obtained by simulation in the design of the semiconductor device DE. The subsequent steps are the same as steps S303, S210, and S211 of the third embodiment.

The consumed power in the semiconductor device DE is affected by the manufacturing process of the wafer WF. Therefore, the consumed power in the semiconductor device DE may vary depending on the position within the plane of the wafer WF. Consequently, the heat generation also varies depending on the position within the plane of the wafer WF. According to this modified example, the temperature adjustment elements 131 are controlled with a correction amount suitable for the heat generation of each semiconductor device DE, allowing the temperature increase at the heat-generating point 136 of the semiconductor device DE to be accurately suppressed.

### Second Modified Example

Next, the inspection apparatus 3 for the semiconductor device DE according to the second modified example of the third embodiment will be described. The configuration of the inspection apparatus 3 in this modified example is the same as the configuration of the inspection apparatus 3 described above. In this modified example, the control unit 220 controls the adjustment unit 230 based on the test results of at least one of the WAT (Wafer Acceptance Test) and the completed tests conducted in advance on the semiconductor device DE.

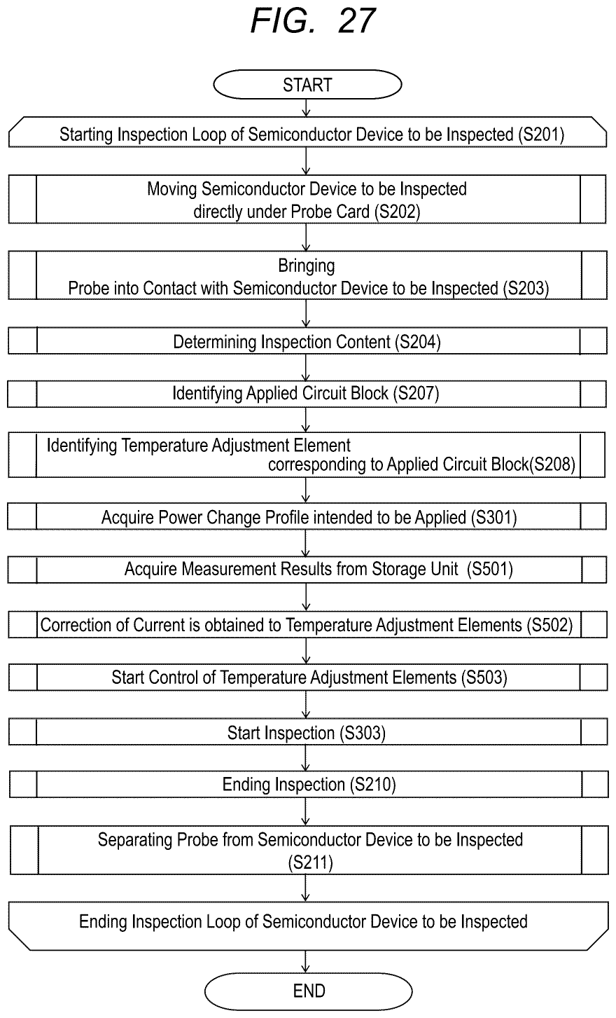

FIG. 27 is a flowchart illustrating the inspection method for the semiconductor device DE according to the second modified example of the third embodiment. As shown in FIG. 27, steps S200 to S301 are the same as in the third embodiment.

In step S501, using the measurement results of the WAT (Wafer Acceptance Test) corresponding to the semiconductor device DE to be inspected, values that allow for the determination of the quality, including the performance of each semiconductor device DE, are retrieved from the storage unit 240.

In step S502, if there is a difference between the obtained measurement results and the expected values, a correction amount of current amount to be applied to the temperature adjustment element 131 is obtained to offset the heat generation corresponding to the difference.

In step S503, the current applied to the temperature adjustment element 131 is controlled based on the obtained correction amount. The subsequent steps are the same as step S303, step S210, and step S211 of the third embodiment. In this modified example, instead of the WAT measurement results, the results of completed inspections may be used. Thus, in this modified example, the adjustment unit 230 is controlled based on at least one of the inspection results of the WAT and completed inspection processes conducted in advance for the semiconductor device DE.

In this modified example as well, it is possible to correspond to the amount of heat generation due to power consumption, taking into account the influence of the wafer WF manufacturing process. As a result, the temperature adjustment element 131 is controlled with a current amount suitable for the heat generation of each semiconductor device DE, thereby accurately suppressing the temperature rise of the heat generation point 136 of the semiconductor device DE.

Although the invention made by the present inventor has been specifically described based on the embodiment, the present invention is not limited to the above embodiment, and it is needless to say that various modifications can be made without departing from the gist thereof. For example, combinations of the configurations of the comparative example, embodiments 1 to 3, and modified examples 1 to 2 are also within the scope of the technical concept of the embodiment. Additionally, the following configurations are also within the scope of the technical concept of the embodiment.

As a method for inspecting the semiconductor device DE, it has been described that the semiconductor device DE is inspected using the probe card 140 and tester 210, but this is not limited to that. For example, the inspection method for the semiconductor device DE may be used for methods that inspect the reflection and absorption of light by irradiating light, or methods that inspect the absorption of magnetism by applying magnetism.

The following semiconductor device inspection program, which executes the inspection method of the semiconductor device DE on a computer, is also within the scope of the technical concept of the embodiment. Such a program can be stored and provided to a computer using various types of non-transitory computer-readable media. Non-transitory computer-readable media include various types of tangible storage media. Examples of non-transitory computer-readable media include magnetic recording media (e.g., flexible disks, magnetic tapes, hard disk drives), magneto-optical recording media (e.g., magneto-optical disks), CD-ROM (Read Only Memory), CD-R, CD-R/W, solid-state memories (e.g., masked ROM, PROM (Programmable ROM), EPROM (Erasable PROM), flash ROM, RAM (Random Access Memory)). The program may also be supplied to the computer by various types of transitory computer-readable media. Examples of transitory computer-readable media include electrical signals, optical signals, and electromagnetic waves. The transitory computer-readable medium may provide the program to the computer via wired or wireless communication paths, such as electrical wires and optical fibers.

### Note A1

An inspection program of a semiconductor device causing a computer to execute inspecting the semiconductor device that is included in a sample placed on a stage of an inspection apparatus for the semiconductor device; wherein the stage includes a temperature adjustment unit, the temperature adjustment unit includes a plurality of temperature adjustment elements, the plurality of temperature adjustment elements are arranged in a plane parallel to a stage surface of the stage where the sample is placed, and a size of each of the plurality of temperature adjustment elements is smaller than or equal to a size of the semiconductor device in a plain view.

### Note A2

The inspection program according to note A1, wherein at least one of the plurality of temperature adjustment elements is controlled differently from the other of the plurality of temperature adjustment elements.

### Note A3

The inspection program according to note A1, wherein the stage includes a temperature control unit, and wherein the inspection method further comprises performing at least one of the heating and cooling by the plurality of temperature adjustment elements controlled by the temperature control unit so that the temperature of the stage reaches a predetermined value.

### Note A4

The inspection program according to note A1, further comprising: measuring the temperature of the semiconductor device with a temperature sensor which is included in the inspection apparatus.

### Note A5

The inspection program according to note A4, wherein the temperature sensor is placed between two adjacent temperature adjustment elements of the plurality of temperature adjustment elements.

### Note A6

The inspection program according to note A4, wherein the temperature sensor is provided on a probe card having probes that contact terminals of the semiconductor device.

### Note A7

The inspection program according to note A1, further comprising: contacting probes of a probe card with terminals of the semiconductor device; and applying a current to the semiconductor device through the probes from a tester for the inspecting the semiconductor device.

### Note A8

The inspection program according to note A1, further comprising: determining inspection items for inspecting the semiconductor device.

### Note A9

The inspection program according to note A1, wherein the semiconductor device includes a plurality of circuit blocks, the size of each of the plurality of temperature adjustment elements is smaller than or equal to a size of at least one of the circuit blocks in a plain view.

### Note A10

The inspection program according to note A1, further comprising: identifying at least one of the circuit blocks to be applied a current to inspect; and determining at least one of the plurality of the temperature adjustment elements located at a position corresponding to the circuit block identified by the identifying.

### Note A11

The inspection program according to note A3, wherein the temperature adjustment unit is arranged between the temperature control unit and the surface of the stage.

### Note A12

The inspection program according to note A1, wherein the inspection apparatus further includes an adjustment unit that controls each of the plurality of temperature adjustment elements.

### Note A13

The inspection program according to note A12, wherein the adjustment unit controls each of the plurality of temperature adjustment elements based on a result of a tester that inspects the semiconductor device by applying a current to the semiconductor device.

### Note A14

The inspection program according to note A12, wherein the adjustment unit controls each of the plurality of temperature adjustment elements based on a result of a temperature sensor that measures temperature of the semiconductor device.

### Note A15

The inspection program according to note A12, wherein the inspection apparatus further includes a storage unit, wherein the adjustment unit controls each of the plurality of temperature adjustment elements based on information of the semiconductor device stored in the storage unit.

### Note A16

The inspection program according to note A12, wherein the adjustment unit controls each of the plurality of temperature adjustment elements based on a power change profile to apply for the semiconductor device.

### Note A17

The inspection program according to note A12, wherein the adjustment unit controls each of the plurality of temperature adjustment elements preceding to applying a power change profile for the semiconductor device.

### Note A18

The inspection program according to note A12, further comprising: measuring a power consumption obtained by applying electrical signals of a sequence of the semiconductor device, wherein the adjustment unit controls each of the plurality of temperature adjustment elements based on a difference between the power consumption by the measuring and a power consumption as simulation result of designing the semiconductor device.

### Note A19

The inspection program according to note A12, wherein the adjustment unit controls each of the plurality of temperature adjustment elements based on a test result of WAT (Wafer Acceptance Test) of the semiconductor device before performing the inspection method of the semiconductor device or a test result of test that has been performed of the semiconductor device.

What is claimed is:

1. An inspection method of a semiconductor device, comprising:
inspecting the semiconductor device that is included in a sample placed on a stage of an inspection apparatus for the semiconductor device,
wherein the stage includes a temperature adjustment unit, and the temperature adjustment unit includes a plurality of temperature adjustment elements,
wherein the plurality of temperature adjustment elements are arranged in a plane parallel to a stage surface of the stage where the sample is placed, and a size of each of the plurality of temperature adjustment elements is smaller than or equal to a size of the semiconductor device in a plain view.

2. The inspection method according to claim 1, wherein at least one of the plurality of temperature adjustment elements is controlled differently from the other of the plurality of temperature adjustment elements.

3. The inspection method according to claim 1, wherein the stage includes a temperature control unit, and
wherein the inspection method further comprises performing at least one of the heating and cooling by the plurality of temperature adjustment elements controlled by the temperature control unit so that the temperature of the stage reaches a predetermined value.

4. The inspection method according to claim 1, further comprising:
measuring the temperature of the semiconductor device with a temperature sensor which is included in the inspection apparatus.

5. The inspection method according to claim 4, wherein the temperature sensor is placed between two adjacent temperature adjustment elements of the plurality of temperature adjustment elements.

6. The inspection method according to claim 4, wherein the temperature sensor is provided on a probe card having probes that contact terminals of the semiconductor device.

7. The inspection method according to claim 1, further comprising:
contacting probes of a probe card with terminals of the semiconductor device; and
applying a current to the semiconductor device through the probes from a tester for the inspecting the semiconductor device.

8. The inspection method according to claim 1, further comprising:
determining inspection items for inspecting the semiconductor device.

9. The inspection method according to claim 1, wherein the semiconductor device includes a plurality of circuit blocks, the size of each of the plurality of temperature adjustment elements is smaller than or equal to a size of at least one of the circuit blocks in a plain view.

10. The inspection method according to claim 1, further comprising:
identifying at least one of the circuit blocks to be applied a current to inspect; and
determining at least one of the plurality of the temperature adjustment elements located at a position corresponding to the circuit block identified by the identifying.

11. The inspection method according to claim 3, wherein the temperature adjustment unit is arranged between the temperature control unit and the surface of the stage.

12. The inspection method according to claim 1, wherein the inspection apparatus further includes an adjustment unit that controls each of the plurality of temperature adjustment elements.

13. The inspection method according to claim 12, wherein the adjustment unit controls each of the plurality of temperature adjustment elements based on a result of a tester that inspects the semiconductor device by applying a current to the semiconductor device.

14. The inspection method according to claim 12, wherein the adjustment unit controls each of the plurality of temperature adjustment elements based on a result of a temperature sensor that measures temperature of the semiconductor device.

15. The inspection method according to claim 12, wherein the inspection apparatus further includes a storage unit, wherein the adjustment unit controls each of the plurality of temperature adjustment elements based on information of the semiconductor device stored in the storage unit.

16. The inspection method according to claim 12, wherein the adjustment unit controls each of the plurality of temperature adjustment elements based on a power change profile to apply for the semiconductor device.

17. The inspection method according to claim 12, wherein the adjustment unit controls each of the plurality of temperature adjustment elements preceding to applying a power change profile for the semiconductor device.

18. The inspection method according to claim 12, further comprising:
measuring a power consumption obtained by applying electrical signals of a sequence of the semiconductor device,
wherein the adjustment unit controls each of the plurality of temperature adjustment elements based on a difference between the power consumption by the measuring and a power consumption as simulation result of designing the semiconductor device.

19. The inspection method according to claim 12, wherein the adjustment unit controls each of the plurality of temperature adjustment elements based on a test result of WAT (Wafer Acceptance Test) of the semiconductor device before performing the inspection method of the semiconductor device or a test result of test that has been performed of the semiconductor device.

20. A non-transitory computer-readable media storing a program causing a computer to implement:
inspecting a semiconductor device that is included in a sample placed on a stage of an inspection apparatus for the semiconductor device,
wherein the stage includes a temperature adjustment unit, the temperature adjustment unit includes a plurality of temperature adjustment elements, the plurality of temperature adjustment elements are arranged in a plane parallel to a stage surface of the stage where the sample is placed, and a size of each of the plurality of temperature adjustment elements is smaller than or equal to a size of the semiconductor device in a plain view.
